(19) United States
(12) Patent Application Publication
(10) Pub. No.: US 2006/0102940 A1
(43) Pub. Date: May 18, 2006

(54) Semiconductor device having a photodetector and method for fabricating the same

(75) Inventors: Yong-Won Cha, Yongin-si (KR); Eun-Kyung Baek, Suwon-si (KR); Kyu-Tae Na, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/280,704

(22) Filed: Nov. 15, 2005

(30) Foreign Application Priority Data
Nov. 16, 2004 (KR) 10-2004-0093648

(51) Int. Cl. H01L 31/062; H01L 21/00

(52) U.S. Cl. 257/294; 438/70; 257/E27.133

(57) ABSTRACT

The present invention is directed to a semiconductor device having a photodetector and a method of fabricating the same. The photodetector includes a visible ray absorbing pattern disposed on a top and/or bottom surface of an interconnection formed at a light shielding area between adjacent photodetectors, which prevents obliquely incident light from reaching an adjacent photodetector.

### RELATED APPLICATION

This application relies for priority on Korean Patent Application number 2004-93648, filed in the Korean Intellectual Property Office on Nov. 16, 2004, the contents of which are incorporated herein in their entirety by reference.

### FIELD OF THE INVENTION

The present invention relates to a semiconductor device and a method for fabricating the same. More specifically, the present invention is directed to a semiconductor device having a photodetector and a method for fabricating the same.

### BACKGROUND OF THE INVENTION

A photodetector measures photo flux or optical power by converting photon energy absorbed by an element into a measurable energy. Typically, photodetectors are classified as thermal detectors or photoelectric detectors. Thermal detectors convert energy into heat but have low efficiency in view of time required for a temperature variation procedure and a relatively lower speed. Photoelectric detectors are based on a photoeffect. That is, carriers such as electrons and holes are generated in materials constituting an element by photons absorbed by the element. Flow of the carriers results in generation of measurable current.

Having advantages such as high sensitivity to operating wavelength, high-speed response, and minimal noise, photodetectors have been widely used in detectors for detecting optical signals in optical fiber telecommunication systems operating at a near infrared ray area (0.8˜1.6 micrometer). Moreover, they have been widely used in image sensors of cameras.

An image sensor has a plurality of pixels that are 2-dimensionally arranged in a matrix. Each of the pixels includes a photodetector as well as transmission and readout devices. Depending on the types of transmission and readout devices, image sensors are classified as charge coupled device image sensors (hereinafter referred to as “CCDs”) or complementary metal oxide semiconductor image sensors (hereinafter referred to as “CISs”). CCDs use MOS capacitors for transmission and readout. Since these MOS capacitors are disposed close together, charge carriers are stored in a capacitor and transmitted to an adjacent capacitor. On the other hand, CISs adopt a switching mode in which MOS transistors are used to detect outputs in succession.

A semiconductor device having a photodetector such as an image sensor include a light transmission area where photodetectors are formed and a shielding area where metal interconnections and light-shielding patterns are formed. Visible rays, i.e., photons, are irradiated to the light transmission area to generate signal charges. The metal interconnections and light-shielding patterns prevent visible rays from transmitting into the shielding area.

Such an image sensor may suffer from cross-talk in which photons that impinge on a target photodetector also impinge on an adjacent photodetector. The cross-talk results in degradation of photosensitivity, which will be described below with reference to FIG. 1.

FIG. 1 is a cross-sectional view illustrating the cross-talk occurring in a conventional CIS image device, in which a reference numeral “a” denotes a light transmission area where photodetectors are formed, and a reference numeral “b” denotes a light shielding area. The CIS image device includes photodetectors 15a and 15b formed at the light transmission area “a” of a substrate 11. Adjacent photodetectors are electrically isolated by a device isolation area 13. A transistor for outputting signal charges formed at a photodetector, metal interconnections 25 and 29, and a shielding pattern 33 are formed at the light shielding area “b”. A first metal interconnection 25, a second metal interconnection 29, and a shielding pattern 33 are disposed over a transistor and are electrically insulated by interlayer dielectrics 23, 27, and 31. A first interlayer dielectric 23 covers a transistor and a photodetector, and the second interlayer dielectric 27 covers a first metal interconnection 25. The third interlayer dielectric 31 covers a second metal interconnection 27. The shielding pattern 33 is disposed on the third interlayer dielectric 31 to cover light shielding area “b”. The metal interconnections 25 and 29 and the shielding pattern 33 are all made of metal.

Since metal has a superior reflection property, most impinging photons are reflected. Therefore, if an obliquely incident light 35 impinging on the light transmission area “a” is irradiated, it does not reach a target photodetector 15b and is reflected by a metal interconnection and a shielding pattern to reach an adjacent photodetector 15a. This is illustrated by the arrows in FIG. 1A. Thus, unwanted signal charges are accumulated at the adjacent photodetector 15a, resulting in information distortion (information bias).

In view of the foregoing, there is a requirement for a semiconductor device having a photodetector which prevents cross-talk caused by oblique incident light.

### SUMMARY OF THE INVENTION

The present invention provides a semiconductor device having a photodetector and a method of fabricating the device in which degradation of photosensitivity is substantially reduced and device reliability is improved.

The present invention also provides a method of forming a visible ray absorbing layer applicable to the semiconductor device having the photodetector.

According to a first aspect, the invention is directed to a semiconductor device having a photodetector. The device includes a metal pattern of at least one layer disposed at a light shielding area adjacent to the photodetector. A visible ray absorbing pattern disposed on at least one of top and bottom surfaces of the metal pattern.

In one embodiment, the visible ray absorbing pattern comprises carbon.

In one embodiment, the visible ray absorbing pattern comprises graphite-like carbon.

The semiconductor device can further include an anti-reflective coating layer disposed on the visible ray absorbing pattern on the top surface of the metal pattern.

The semiconductor device can further include a spacer-type visible ray absorbing pattern disposed on lateral faces of the metal pattern.

In one embodiment, the metal pattern includes a metal interconnection of at least one layer and a shielding pattern.

In one embodiment, the visible ray absorbing pattern on the top surface of the metal pattern has a convex top surface.

In one embodiment, the visible ray absorbing pattern disposed on the top surface of the metal pattern is thicker than the visible ray absorbing pattern disposed on the bottom surface of the metal pattern.

According to another aspect, the invention is directed to a method for forming a visible ray absorbing pattern. According to the method, the visible ray absorbing pattern is formed by a plasma chemical vapor deposition (CVD), wherein the plasma CVD uses a hydrocarbon gas as a carbon source.

In one embodiment, the plasma CVD is performed under conditions in which a flow rate of the hydrocarbon gas is about 100˜6,000 sccm, a deposition temperature is about 100˜700 degrees centigrade, a pressure is about 1˜20 Torr, and a power is 100˜300 watts. The plasma CVD can use a carrier gas of a flow rate ranging from 0 sccm to 5,000 sccm. The carrier gas can be an inert gas or hydrogen gas.

According to another aspect, the invention is directed to a method for fabricating a semiconductor device. According to the method, a photodetector is formed on a light receiving area of a semiconductor substrate. A metal pattern of at least one layer is formed on a light shielding area of the semiconductor substrate between adjacent photodetectors. A visible ray absorbing pattern is formed on top and/or bottom surfaces of the metal pattern.

Forming the metal pattern can include forming an insulation layer on the light shielding area; forming a conductive layer and a visible ray absorbing layer on the insulation layer; and pattering the visible ray absorbing layer and the conductive layer.

Forming the metal pattern can include forming an insulation layer on the light shielding area; forming a visible ray absorbing layer and a conductive layer on the insulation layer; and pattering the conductive layer and the visible ray absorbing layer.

Forming the metal pattern can include forming an insulation layer on the light shielding area; forming a lower visible ray absorbing layer, a conductive layer, and an upper visible ray absorbing layer on the insulation layer; and patterning the upper visible ray absorbing layer, the conductive layer, and the lower visible ray absorbing layer.

Forming the visible ray absorbing layer can be done by plasma chemical vapor deposition (CVD) using a hydrocarbon gas as a carbon source. The plasma CVD can be performed under conditions in which a flow rate of the hydrocarbon gas is about 100˜6,000 sccm, a deposition temperature is about 100˜700 degrees centigrade, a pressure is about 1˜20 Torr, and a power is 100˜300 watts. The plasma CVD can use a carrier gas of a flow rate ranging from 0 sccm to 5,000 sccm. The carrier gas can be an inert gas or hydrogen gas.

The method can further include forming a spacer-type visible ray absorbing pattern on sidewalls of the metal pattern.

According to another aspect, the invention is directed to a method for fabricating a semiconductor device, comprising: forming photodetectors on a light receiving area of a semiconductor substrate; forming a first insulation layer on the light receiving area between adjacent photodetectors; forming a first interconnection on the first insulation layer to be electrically connected to the semiconductor substrate of the light shielding area through the first insulation layer; forming a second insulation layer on the first interconnection and the first insulation layer; forming a second interconnection on the second insulation layer to be electrically connected to the first interconnection through the second insulation layer; forming a third insulation layer on the second interconnection and the second insulation layer; forming a shielding pattern on the third insulation layer; and forming a fourth insulation layer on the shielding pattern. A visible ray absorbing layer can be formed before or after formation or before and after formation of the metal interconnection and the shielding pattern.

In one embodiment, the visible ray absorbing layer is formed by plasma chemical vapor deposition (CVD) using a hydrocarbon gas as a carbon source. The plasma CVD can be performed under conditions in which a flow rate of the hydrocarbon gas is about 100˜6,000 sccm, a deposition temperature is about 100˜700 degrees centigrade, a pressure is about 1˜20 Torr, and a power is 100˜300 watts. The plasma CVD can use a carrier gas of a flow rate ranging from 0 sccm to 5,000 sccm. The carrier gas can be an inert gas or hydrogen gas.

The method can further include forming a spacer-type visible ray absorbing pattern on sidewalls of the metal interconnection and the shielding pattern.

In one embodiment, the visible ray absorbing layer is formed by a spin-on-glass (SOG) manner using a chemical having a graphite-like carbon structure.

According to another aspect, the invention is directed to a semiconductor device having a photodetector. The device includes a metal interconnection of at least one layer disposed at a light shielding area between adjacent photodetectors. A shielding pattern is disposed on the highest layer of the metal interconnection of at least one layer to cover the light shielding area. A visible ray absorbing pattern is disposed on at least one of top and bottom surfaces of the metal interconnection and the shielding pattern.

In an exemplary embodiment, a semiconductor device having a photodetector includes an absorbing pattern.

The semiconductor device having the photodetector includes a light transmission area where the photodetector is formed and a light shielding area adjacent to the photodetector. The light shielding area includes a metal pattern of at least one layer. The metal pattern may include, for example, a metal interconnection of at least one layer and a shielding pattern.

Visible rays are irradiated to an area exposed by the shielding pattern, i.e., the light transmission area, to generate signal charges at the photodetector of the light transmission area.

An absorbing pattern is formed on at least one of top and bottom surfaces of the metal interconnection and the shielding pattern. Thus, an obliquely incident light irradiated to the light transmission area is absorbed by the absorbing pattern to prevent irradiation of the obliquely incident light to an unwanted photodetector.

The absorbing pattern is made of a material absorbing visible rays, e.g., carbon. Preferably, the absorbing pattern is made of graphite-like carbon. A layer of the graphite-like carbon has a high light absorptivity at a visible ray area.

The photodetector may be for example, a photodiode, a phototransistor, a pinned diode, a photogate, or a MOSFET, and is not limited thereto.

The signal charges generated from the photodetector are read out by applying a suitable voltage to a gate and a metal interconnection of respective transistors formed at the light shielding area.

The absorbing pattern may be formed by performing plasma chemical vapor deposition (CVD) using a hydrocarbon gas as a carbon source. The plasma CVD may be performed under conditions in which, for example, a flow rate of hydrocarbon gas is 100˜6,000 sccm, a pressure is 1˜20 Torr, and a power is 100˜300 watts.

The plasma CVD may further use carrier gas for carrying the hydrocarbon gas into a reaction chamber. The carrier gas includes, for example, inert gas or hydrogen gas. The inert gas contains, for example, nitrogen gas, argon gas, and/or helium gas. The carrier gas is supplied to the reaction chamber at a flow rate ranging from 0 sccm to 5,000 sccm.

The absorbing pattern may be formed by a spin-on-glass (SOG) technique using a chemical having a graphite-like carbon structure. A layer of graphite-like carbon is formed by performing a bake process at a temperature of 100˜500 degrees centigrade to remove water after performing a spin coating for a chemical having a graphite-like carbon structure. Preferably, after performing the bake process, an annealing process is performed in a nitrogen ambient at a temperature of 100˜700 degrees centigrade or an annealing process is performed using a hot-plate process at a temperature of 100˜500 degrees centigrade.

In an exemplary embodiment, a method of fabricating a semiconductor device having a photodetector includes forming a photodetector on a light receiving area of a semiconductor substrate; and forming a metal pattern of at least one layer on a light shielding area of a semiconductor substrate between adjacent photodetectors. A visible ray absorbing pattern is formed on at least one of top and bottom surface of the metal pattern.

In some embodiments of the present invention, the formation of the metal pattern includes forming an insulation layer on the light shielding area; forming a conductive layer and a visible ray absorbing layer on the insulation layer; and pattering the visible ray absorbing layer and the conductive layer.

In some embodiments of the present invention, the formation of the metal pattern includes forming an insulation layer on the light shielding area; forming a visible ray absorbing layer and a conductive layer on the insulation layer; and pattering the conductive layer and the visible ray absorbing layer.

In some embodiments of the present invention, the formation of the metal pattern includes forming an insulation layer on the light shielding layer; forming a lower visible ray absorbing layer, a conductive layer, and an upper visible ray absorbing layer on the insulation layer; and patterning the upper visible ray absorbing layer, the conductive layer, and the lower visible ray absorbing layer.

In some embodiments of the present invention, the method may further include forming a spacer-type visible ray absorbing pattern on sidewalls of the metal pattern after patterning the upper visible ray absorbing layer, the conductive layer, and the lower visible ray absorbing layer.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a cross-sectional view illustrating the cross-talk in a conventional CIS image device.

FIG. 2 is a cross-sectional view of a semiconductor substrate, which shows a part of a CIS image sensor according to the present invention.

FIG. 3 is a graph which illustrates absorbance (k) and refractive index (n) relative to graphite-like carbon depending on various wavelengths.

FIG. 4 illustrates a structure of graphite-like carbon.

FIG. 5 is a schematic diagram which illustrates an absorbing pattern according to the present invention.

FIG. 6 through FIG. 10 are cross-sectional views illustrating a method of fabricating the semiconductor device shown in FIG. 2.

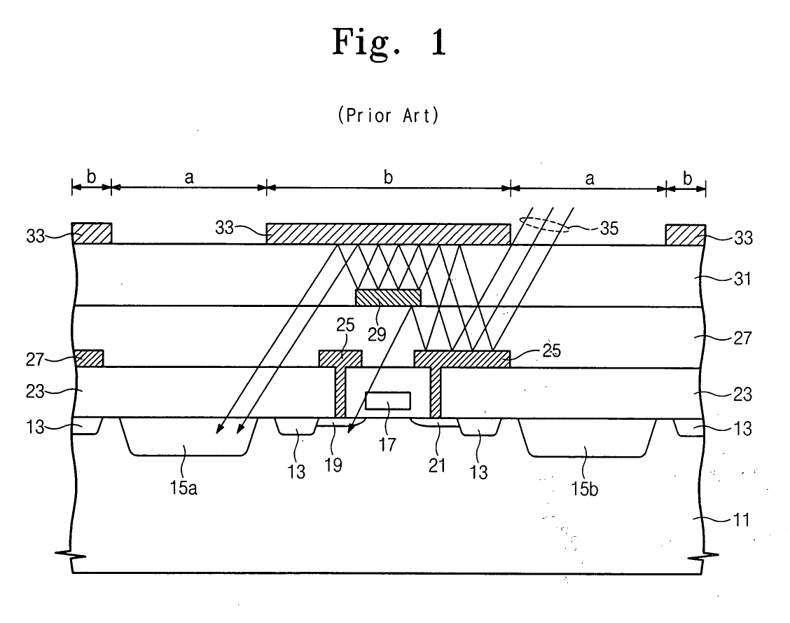

### DETAILED DESCRIPTION OF THE INVENTION

The present invention now will be described more fully hereinafter with reference to the accompanying drawings, in which embodiments of the invention are shown. It will be understood that when an element such as a layer, region or substrate is referred to as being “on” or extending “onto” another element, it can be directly on or extend directly onto the other element or intervening elements may also be present.

Although the present invention relates to a semiconductor device having a photodetector and a method of fabricating the same, a CIS image sensor will be described herein by way of example. Nonetheless, the invention may be applied to the CIS image sensor as well as all semiconductor devices having a photodetector such as a CCD image sensor and an optical sensor.

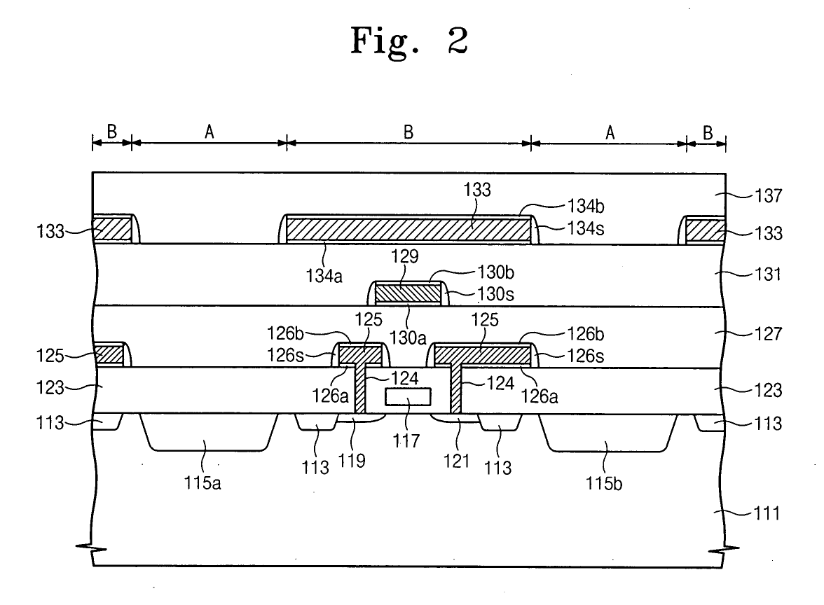

FIG. 2 is a cross-sectional view of a semiconductor substrate, which shows a CIS image sensor according to an embodiment of the present invention. In FIG. 2, reference character “A” denotes a light receiving area where photodetectors are formed, and a reference character “B” denotes a light shielding area.

Referring to FIG. 2, the CIS image sensor includes photodetectors 115a and 115b formed at a light receiving area “A” of a substrate 111, a transistor formed at a light shielding area “B” of the substrate 111, metal interconnections, and a shielding pattern. To clarify description and simplify the figure, one transistor and a two-level metal interconnection are illustrated. A metal interconnection may be a single-level metal interconnection, a triple-level metal interconnection, or other metal interconnection, and at least two transistors may be formed.

Each of the photodetectors 115a and 115b is not limited to the type described herein. For example, the photodetectors 115a and 115b may be, for example, photodiodes, phototransistors, pinned photodiodes, photogates, or MOSFETs. In order to form a photodiode, an epitaxial N-type silicon layer is formed on a P-type substrate 111. Impurities for an N-type region of a photodiode are implanted into the N-type epitaxial layer to form an N-type region. P-type impurities are implanted into a surface of the N-type region to form a P-type region. As a result, a PN junction photodiode is formed. Signal charges are generated at an N-type region of a photodiode by photons. Following formation of an N-type epitaxial silicon layer, a deep P-type well may be formed between the P-type substrate and the N-type epitaxial silicon layer. The deep P-type well acts as a barrier layer for preventing the signal charges from leaking out to the P-type substrate.

A transistor includes a gate 117 formed on the substrate 111 and impurity regions 119 and 121 formed at the substrate at opposite sides of the gate 117. A device isolation region 113 electrically isolates adjacent photodetectors 115a and 115b.

A first interlayer dielectric 123 is disposed on the substrate 111 to insulate photodetectors 115a and 115b from the transistor. A first metal interconnection 125 is disposed on the first interlayer dielectric 123 and is electrically connected to the impurity regions 119 and 121 of the transistor through contact holes 124 formed in the first interlayer dielectric 123.

A second interlayer dielectric 127 is disposed on the first interlayer dielectric 123 and the first metal interconnection 125. A second metal interconnection 129 is disposed on the second interlayer dielectric 127 and over the first metal interconnection 125. Although not shown in this figure, a portion of the second metal interconnection 129 is electrically connected to a portion of the first metal interconnection 125.

A third interlayer dielectric 131 is formed on the second interlayer dielectric 127 and the second metal interconnection 129, and a shielding pattern 133 is disposed over the third interlayer dielectric 131 and the second metal interconnection 129. The light receiving area “A” is exposed to allow incident light to be irradiated to the light receiving area “A”. A fourth interlayer dielectric 137 is disposed on the shielding pattern 133 and the third interlayer dielectric 131.

Each of the interlayer dielectrics 123, 127, 131, and 137 is made of an oxide which can transmit visible rays. The metal interconnections 125, 129 and the shielding pattern 133 can be made of material having a high transmissivity relative to visible rays, e.g., at least one material selected from the group consisting of aluminum, aluminum-alloy, copper, copper-alloy, and combinations thereof.

Absorbing patterns 126a, 126b, 130a, 130b, 134a and 134b are disposed at bottom and top surfaces of the metal interconnections 125 and 129 and the shielding pattern 133. Specifically, metal patterns 126a and 126b are disposed on bottom and top surfaces of the first metal interconnection 125, respectively; metal patterns 130a and 130b are disposed on bottom and top surfaces of the second metal interconnection 129, respectively; and metal patterns 134a and 134b are disposed on bottom and top surfaces of the shielding pattern 133, respectively.

The absorbing patterns 126a, 126b, 130a, 130b, 134a and 134b may be formed on one of top and bottom surfaces of the metal interconnections 125 and 129 and the shielding pattern 133, respectively.

Spacer-type metal patterns 126s, 130s, and 134s may be disposed on lateral faces of the metal interconnections 125 and 129 and the shielding pattern 133, respectively. In this case, the metal interconnections 125 and 129 and the shielding pattern 133 are fully covered with a shielding pattern.

Each of the absorbing patterns 126a, 126b, 130a, 130b, 134a and 134b is made of a material having a high transmissivity relative to rays within a visible ray zone. Each of them is made of, for example, carbon. Preferably, each of them is made of graphite-like carbon.

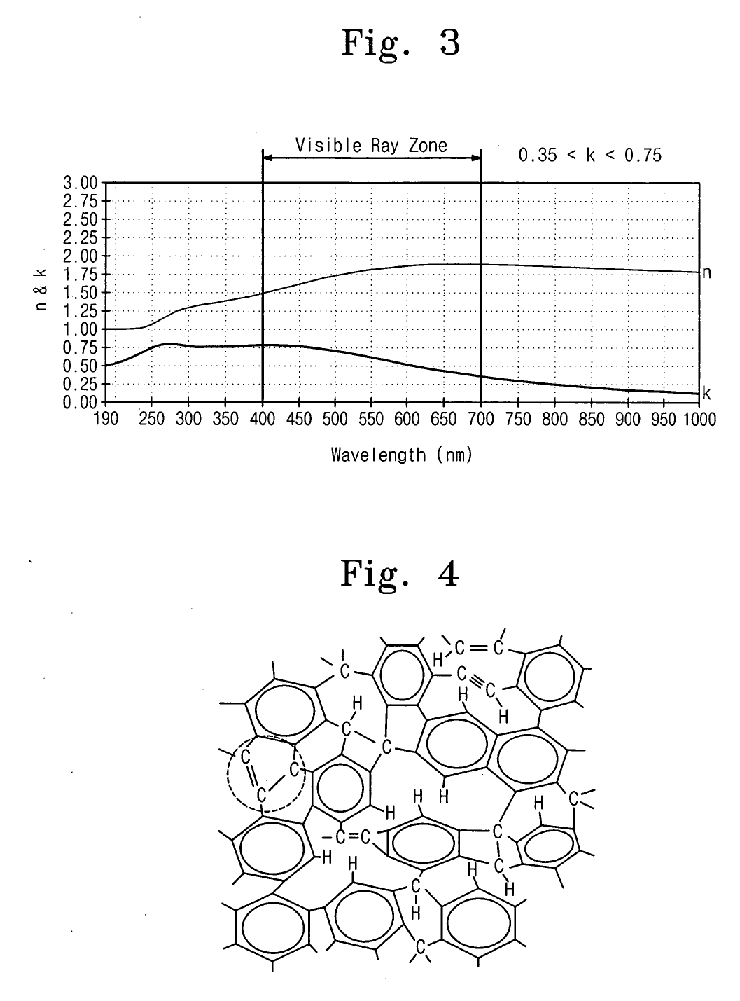

FIG. 3 shows absorbance (k) and refractive index (n) relative to graphite-like carbon with respect to various wavelengths. As illustrated in FIG. 3, the graphite-like carbon has a higher absorbance at wavelengths within the visible ray zone.

FIG. 4 shows a structure of graphite-like carbon. Graphite-like carbon is a layer of carbon containing a coupling structure (π-conjugation) indicated by a dotted line. The greater π-conjugation is, the more bandgap (Eg) decreases, thereby increasing absorbance within the visible ray zone. That is, most of the photons having higher energy than the bandgap (Eg) between a conduction band and a valence band are absorbed. That is, because graphite-like carbon has a smaller bandgap (Eg), most of the photons are absorbed in the graphite-like carbon.

Returning to FIG. 2, the absorbing patterns 126a, 126b, 130a, 130b, 134a and 134b are formed on top and bottom surfaces of a metal interconnection and top and bottom surfaces of a shielding pattern, as previously stated. Therefore, an obliquely incident light is absorbed by the absorbing patterns 126a, 126b, 130a, 130b, 134a and 134b before reaching an adjacent photodetector 115a.

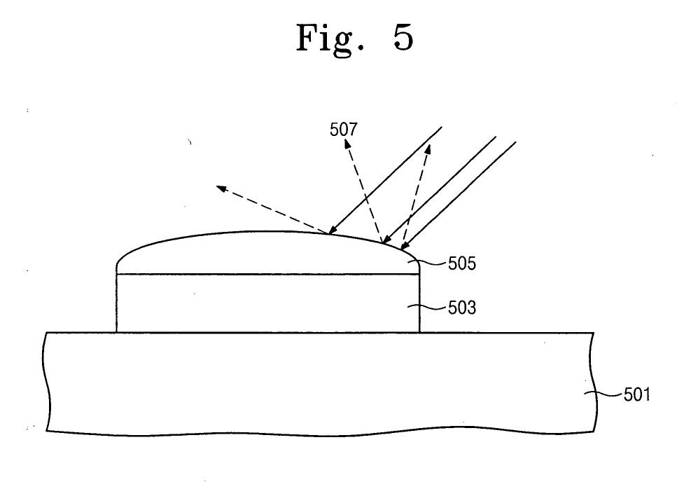

FIG. 5 shows an absorbing pattern 505 according to another embodiment of the present invention. In FIG. 5, reference numeral 501 denotes an insulation layer or a substrate and reference numeral 503 denotes a metal interconnection. Since the absorbing pattern 505 has a convex top, obliquely incident light 507 unabsorbed by the absorbing pattern 505 is irregularly reflected by a surface of the absorbing pattern 505. Thus, irregularly reflected photons are not concentrated on one photodetector. In this regard, if the absorbing pattern 505 is made of graphite-like carbon and has a convex top, occurrence of cross-talk is suppressed more efficiently. Since the absorbing pattern 505 has the convex top, it may be made of a material having a high absorbance as well as a material having a relatively lower absorbance.

A method for forming the absorbing pattern will now be described more fully. A method for forming an absorbing pattern made of graphite-like carbon will be described by way of example. A layer of the graphite-like carbon may be formed using a conventional deposition technique such as, for example, chemical vapor deposition (CVD), plasma CVD or spin-on-glass (SOG). Hereinafter, a method of forming a graphite-like carbon layer using plasma CVD will be described by way of example.

A plasma CVD apparatus is well known to those skilled in the art and will not be described in further detail. A typical plasma CVD apparatus has a reaction chamber. A substrate to be treated is placed in the reaction chamber, and source gases for desired layers flow into the chamber. Plasma is generated in the process chamber.

As described above, a layer of graphite-like carbon containing a high amount of π-conjugation is preferably formed in order to enhance absorbance relative to a visible ray zone of a graphite-like carbon layer. A carbon source employs hydrocarbon such as, for example, CH₄, C₂H₄, C₂H₆, C₃H₆, C₆H₆, and mixtures thereof.

Hydrocarbon gas flows into the reaction chamber at a flow rate of 100˜6,000 sccm. A deposition temperature in the reaction chamber is about 100˜700 degrees centigrade, and pressure in the chamber is about 1˜20 Torr. A bias power for generating plasma is about 100˜300 watts.

Optionally, carrier gas may be further used to carry the hydrocarbon into the reaction chamber. The carrier gas can include, for example, inert gas, hydrogen gas, or other such gas. The inert gas can include, for example, nitrogen gas, argon gas, and helium gas. The carrier gas is supplied to the reaction chamber at a flow rate of, for example, 0˜5,000 sccm.

Alternatively, the graphite-like carbon layer may be formed using an SOG process. According to the SOG process, a chemical having a graphite-like carbon structure is spin-coated, and a bake process is performed to remove water. Duration of the bake process is, for example, 30 seconds to one minute. A temperature of the bake process may range from 100 degrees centigrade to 500 degrees centigrade.

Preferably, the bake process is followed by an annealing process. Duration of the annealing process is relatively longer than that of the bake process. The annealing process is performed in a furnace and a nitrogen gas ambient at a temperature of about 100˜700 degrees centigrade or using a hot plate within a temperature range of 100 to 500 degrees centigrade.

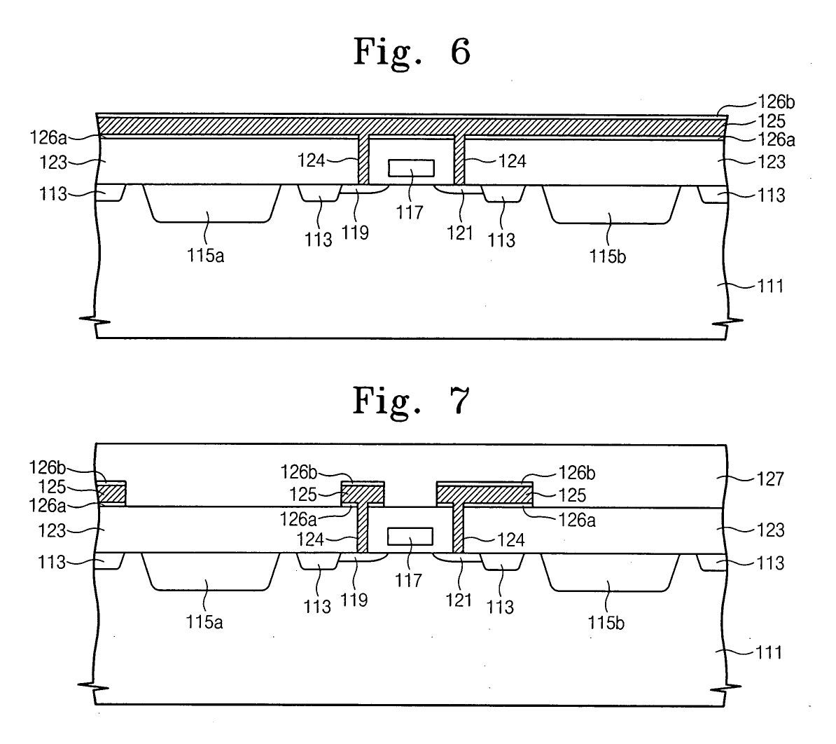

A method of fabricating a semiconductor device having the foregoing absorbing pattern will now be described with reference to FIG. 6 through FIG. 10, which are cross-sectional views of a semiconductor device in accordance with the invention. Although at least one transistor is required for outputting signal charges generated at a photodetector, an active region where photodetectors and transistors are formed may have various shapes based on devices. Photodetectors 115a and 115b are formed using a conventional manner. A photodetector is a device which generates signal charges, e.g., electron-hole pairs, using photons irradiated thereto and may be formed using various approaches. Photodetectors are well known to those skilled in the art. Each of the photodetectors 115a and 115b may be, for example, a photodiode, a phototransistor, a pinned photodiode, a photogate, or a MOSFET. Methods of forming such photodetectors are well known to those skilled in the art and will not be described in further detail.

At least one transistor is formed using a conventional process. The transistor includes a gate 117 and impurity regions 119 and 121 formed at a substrate on opposite sides of the gate 117. The gate 117 is electrically insulated from a substrate 111 by a gate insulation layer.

Referring to FIG. 6, a first interlayer dielectric 123 and a first lower absorbing layer 126a are formed and patterned to form contact holes 124 exposing impurity regions 119 and 121. The first interlayer dielectric 123 may be made of silicon oxide using chemical vapor deposition (CVD), and the first lower absorbing layer 126a may be made of graphite-like carbon. A first conductive layer 125 is formed on the first lower absorbing layer 126a to form a first interconnection. The first conductive layer 125 fills the contact holes 124. A first upper absorbing layer 126b is formed on the first conductive layer 125. The first upper absorbing layer 126b is made of graphite-like carbon, as previously described. The first conductive layer 125 may be made of a metal such as aluminum, copper or an alloy thereof.

Referring to FIG. 7, the first upper absorbing layer 126b, the first metal layer 125, and the first lower absorbing layer 126a are patterned to form a first metal interconnection 125 sandwiched between the absorbing layers 126a and 126b. Thereafter, CVD is used to form a second interlayer dielectric 127, which is made of silicon oxide. Patterning the first upper absorbing layer 126b, the first metal layer 125, and the first lower absorbing layer 126a is done using a conventional photolithographic process. A silicon nitride layer or a silicon oxynitride layer may be further formed on the first upper absorbing layer 126b as an anti-reflective coating layer.

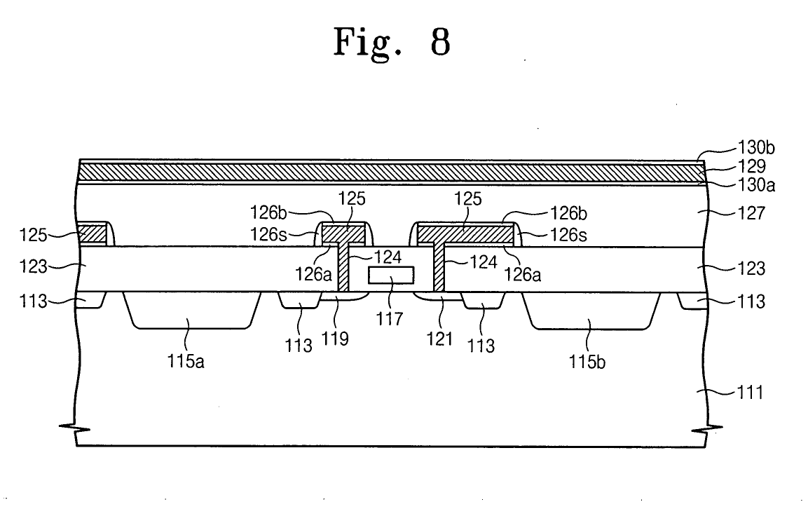

Referring to FIG. 8, a second lower absorbing layer 130a, a second metal layer 129, and a second upper absorbing layer 130b are formed on the second interlayer dielectric 127. Formation of the second lower absorbing layer 130a, the second metal layer 129, and the second upper absorbing layer 130b may be done using the same process as that used in the formation of the first lower absorbing layer 126a, the first metal layer 125, and the first upper absorbing layer 126b. That is, the second lower absorbing layer 130a and the second upper absorbing layer 130b may be made of graphite-like carbon. One of the second upper and lower absorbing layers 130b and 130a may be omitted.

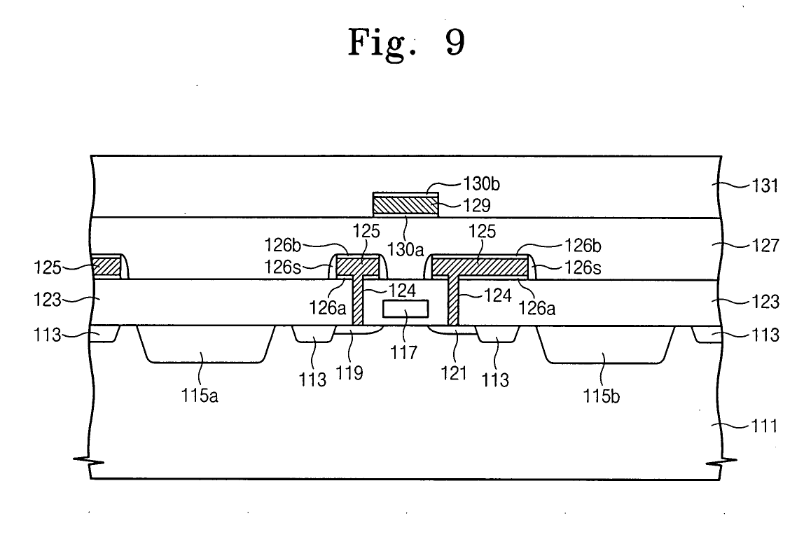

Referring to FIG. 9, the second upper absorbing layer 130b, the second metal layer 129, and the second lower absorbing layer 130a are patterned to form a second metal interconnection 129 sandwiched between the absorbing patterns 130a and 130b. Thereafter, CVD is used to form a third interlayer dielectric 131 made of silicon oxide.

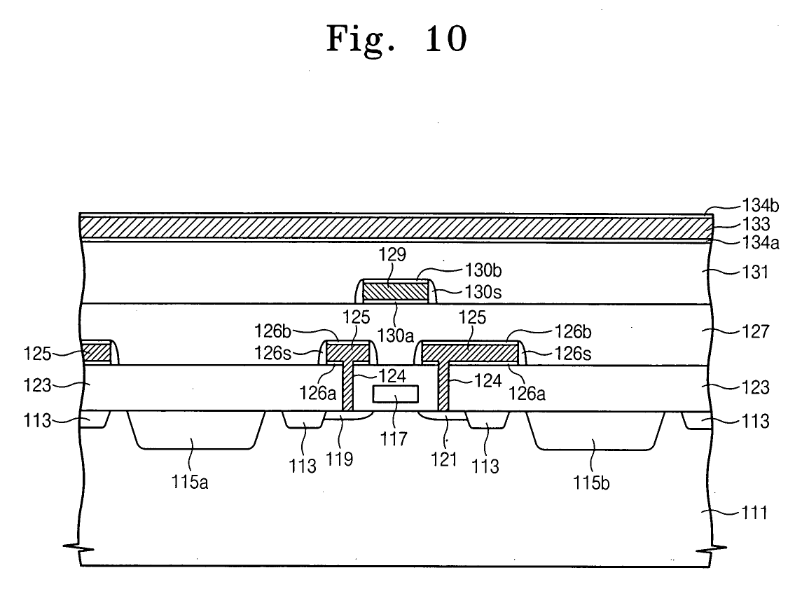

Referring to FIG. 10, a third lower absorbing layer 134a, a shielding layer 133, and a third upper absorbing layer 134b are formed on the third interlayer dielectric 131. The third lower absorbing layer 134a and the third upper absorbing layer 134b may be made of graphite-like carbon. The shielding layer 133 is made of a material to shield light irradiated from a visible ray zone, e.g., aluminum or copper. One of the third upper and lower absorbing layers 134b and 134a may be omitted.

The third upper absorbing layer 134b, the shielding layer 133, and the third lower absorbing layer 134a are patterned to form a shielding pattern 133 sandwiched between the absorbing patterns 134a and 134b, as illustrated in FIG. 2. A fourth interlayer dielectric 137 is then formed.

In the foregoing method, an upper absorbing layer formed on a metal layer and a shielding layer may be thicker than a lower absorbing layer formed below the metal layer and the shielding layer. Thus, the upper absorbing layer may be used as a hard mask while the metal layer is etched.

Further, by controlling the etching condition of an absorbing layer and a metal layer or an absorbing layer and a shielding layer, an absorbing pattern may be formed on the metal layer and the shielding layer to have a convex top. For example, where an absorbing pattern is used as a hard mask for an etch process of an underlying metal layer or shielding layer, the edge of the absorbing layer is etched more by an etch gas than the center thereof. Thus, the absorbing pattern may have a convex top.

As described herein, a layer of a material having an excellent absorbing property relative to visible rays, e.g., a graphite-like carbon layer, is formed on at least one of top and bottom surfaces of a metal interconnection and a shielding pattern to suppress the cross-talk of a semiconductor device having a photodetector. Since the shielding pattern is formed to have a convex top, an irregular reflection arises to prevent obliquely incident light from concentrating on a specific photodetector.

While the present invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents, and alternatives falling within the spirit and scope of the invention as defined by the following appended claims.

What is claimed is:

1. A semiconductor device having a photodetector, comprising:
a metal pattern of at least one layer disposed at a light shielding area adjacent to the photodetector; and
a visible ray absorbing pattern disposed on at least one of top and bottom surfaces of the metal pattern.

2. The semiconductor device of claim 1, wherein the visible ray absorbing pattern comprises carbon.

3. The semiconductor device of claim 1, wherein the visible ray absorbing pattern comprises graphite-like carbon.

4. The semiconductor device of claim 1, further comprising an anti-reflective coating layer disposed on the visible ray absorbing pattern on the top surface of the metal pattern.

5. The semiconductor device of claim 1, further comprising a spacer-type visible ray absorbing pattern disposed on lateral faces of the metal pattern.

6. The semiconductor device of claim 1, wherein the metal pattern includes a metal interconnection of at least one layer and a shielding pattern.

7. The semiconductor device of claim 1, wherein the visible ray absorbing pattern on the top surface of the metal pattern has a convex top surface.

8. The semiconductor device of claim 1, wherein the visible ray absorbing pattern disposed on the top surface of the metal pattern is thicker than the visible ray absorbing pattern disposed on the bottom surface of the metal pattern.

9. A method for forming a visible ray absorbing pattern, comprising forming the visible ray absorbing pattern by a plasma chemical vapor deposition (CVD), wherein the plasma CVD uses a hydrocarbon gas as a carbon source.

10. The method of claim 9, wherein the plasma CVD is performed under conditions in which a flow rate of the hydrocarbon gas is about 100˜6,000 sccm, a deposition temperature is about 100˜700 degrees centigrade, a pressure is about 1˜20 Torr, and a power is 100˜300 watts.

11. The method of claim 10, wherein the plasma CVD uses a carrier gas of a flow rate ranging from 0 sccm to 5,000 sccm.

12. The method of claim 11, wherein the carrier gas is one of an inert gas and hydrogen gas.

13. A method for fabricating a semiconductor device, comprising:
forming a photodetector on a light receiving area of a semiconductor substrate; and
forming a metal pattern of at least one layer on a light shielding area of the semiconductor substrate between adjacent photodetectors; wherein
a visible ray absorbing pattern is formed on at least one of top and bottom surfaces of the metal pattern.

14. The method of claim 13, wherein forming the metal pattern comprises:
forming an insulation layer on the light shielding area;
forming a conductive layer and a visible ray absorbing layer on the insulation layer; and
pattering the visible ray absorbing layer and the conductive layer.

15. The method of claim 13, wherein forming the metal pattern comprises:
forming an insulation layer on the light shielding area;
forming a visible ray absorbing layer and a conductive layer on the insulation layer; and
pattering the conductive layer and the visible ray absorbing layer.

16. The method of claim 13, wherein forming the metal pattern comprises:
forming an insulation layer on the light shielding area;
forming a lower visible ray absorbing layer, a conductive layer, and an upper visible ray absorbing layer on the insulation layer; and
patterning the upper visible ray absorbing layer, the conductive layer, and the lower visible ray absorbing layer.

17. The method of claim 14, wherein forming the visible ray absorbing layer is done by a plasma chemical vapor deposition (CVD) using a hydrocarbon gas as a carbon source.

18. The method of claim 17, wherein the plasma CVD is performed under conditions in which a flow rate of the hydrocarbon gas is about 100˜6,000 sccm, a deposition temperature is about 100˜700 degrees centigrade, a pressure is about 1˜20 Torr, and a power is 100˜300 watts.

19. The method of claim 18, wherein the plasma CVD uses a carrier gas of a flow rate ranging from 0 sccm to 5,000 sccm.

20. The method of claim 19, wherein the carrier gas is one of an inert gas and hydrogen gas.

21. The method of claim 13, further comprising forming a spacer-type visible ray absorbing pattern on sidewalls of the metal pattern.

22. A method for fabricating a semiconductor device, comprising:
forming photodetectors on a light receiving area of a semiconductor substrate;
forming a first insulation layer on the light receiving area between adjacent photodetectors;
forming a first interconnection on the first insulation layer to be electrically connected to the semiconductor substrate of the light shielding area through the first insulation layer;
forming a second insulation layer on the first interconnection and the first insulation layer;
forming a second interconnection on the second insulation layer to be electrically connected to the first interconnection through the second insulation layer;
forming a third insulation layer on the second interconnection and the second insulation layer;
forming a shielding pattern on the third insulation layer; and
forming a fourth insulation layer on the shielding pattern; wherein
a visible ray absorbing layer is formed before or after formation or before and after formation of the metal interconnection and the shielding pattern.

23. The method of claim 22, wherein the visible ray absorbing layer is formed by plasma chemical vapor deposition (CVD) using a hydrocarbon gas as a carbon source.

24. The method of claim 23, wherein the plasma CVD is performed under conditions in which a flow rate of the hydrocarbon gas is about 100˜6,000 sccm, a deposition temperature is about 100˜700 degrees centigrade, a pressure is about 1˜20 Torr, and a power is 100˜300 watts.

25. The method of claim 23, wherein the plasma CVD uses a carrier gas of a flow rate ranging from 0 sccm to 5,000 sccm.

26. The method of claim 24, wherein the carrier gas is one of an inert gas and hydrogen gas.

27. The method of claim 22, further comprising forming a spacer-type visible ray absorbing pattern on sidewalls of the metal interconnection and the shielding pattern.

28. The method of claim 22, wherein the visible ray absorbing layer is formed by a spin-on-glass (SOG) manner using a chemical having a graphite-like carbon structure.

29. A semiconductor device having a photodetector, comprising:
a metal interconnection of at least one layer disposed at a light shielding area between adjacent photodetectors; and
a shielding pattern disposed on the highest layer of the metal interconnection of at least one layer to cover the light shielding area; wherein
a visible ray absorbing pattern is disposed on at least one of top and bottom surfaces of the metal interconnection and the shielding pattern.
